(19) United States
(12) Patent Application Publication
(10) Pub. No.: US 2026/0314152 A1
(43) Pub. Date: Oct. 8, 2026

(54) LIGHT-EMITTING ELEMENT PACKAGE AND METHOD FOR FORMING THE SAME

(71) Applicant: Ennostar Corporation, Hsinchu City (TW)

(72) Inventors: Shu-Wei CHEN, Hsinchu City (TW); Pei-Lun CHEN, Hsinchu City (TW); Jia-Jhang KUO, Hsinchu City (TW)

(21) Appl. No.: 19/640,554

(22) Filed: Apr. 7, 2026

(30) Foreign Application Priority Data
Apr. 7, 2025 (TW) 114112950

(51) Int. Cl. H10H 29/85; H10H 29/01; H10H 29/24

(52) U.S. Cl. CPC H10H 29/857; H10H 29/0364; H10H 29/24; H10H 29/8506

(57) ABSTRACT

A light-emitting element package includes a cup-shaped casing, a first connector, and a first light-emitting element. The casing has an upper portion with a receiving region and a lower portion with a first longer-side surface extending in a first direction and a first shorter-side surface extending in a second direction. The first connector on one side of the lower casing includes a first extension on the upper surface, a second extension on the shorter-side surface, and a third extension on the longer-side surface. The light-emitting element is disposed in the receiving region and electrically connected to the connector.

### CROSS REFERENCE TO RELATED APPLICATIONS

This Application claims priority of Taiwan Patent Application No. 114112950, filed on Apr. 07, 2025, the entirety of which is incorporated by reference herein.

### BACKGROUND OF THE INVENTION

### Field of the Invention

The present disclosure relates to light-emitting element packages and methods for forming the same. In particular, it relates to a light-emitting element package including connectors and methods for forming the same.

### Description of the Related Art

Light-emitting diodes (LEDs) have the advantages such as low power consumption, long component life, no warm-up time, and fast response speed, and have thus been widely adopted in various light-emitting elements. Generally speaking, a light-emitting diode chip is disposed in a region formed by a casing (e.g., a plastic lamp casing) and combined with an electrical connector (e.g., in the form of a lead frame) to form a light-emitting component package.

However, the configuration of the electrical connectors in the existing light-emitting element packages is likely to cause adverse effects when the light-emitting element packages are combined with other components or mounted to other components. Therefore, there are still some issues to be addressed regarding light-emitting element packages.

### BRIEF SUMMARY OF THE INVENTION

Some embodiments disclosed herein provide a light-emitting element package, including: a cup-shaped casing, a first connector, and a first light-emitting element. The cup-shaped casing has an upper portion of the casing and a lower portion of the casing. The upper portion of the casing has a receiving region. The lower portion of the casing has a first longer-side surface and a first shorter-side surface. The first longer-side surface extends along a first direction, and the first shorter-side surface extends along a second direction. The first connector is disposed on a first side of the lower portion of the casing and includes a first extension portion, a second extension portion, and a third extension portion. The first extension portion is disposed on the upper surface of the lower portion of the casing. The second extension portion is connected to the first extension portion and extends on the first shorter-side surface of the lower portion of the casing. The third extension portion is connected to the second extension portion and extends on the first longer-side surface of the lower portion of the casing. The first light-emitting element is disposed in the receiving region and is electrically connected to the first connector.

The light-emitting element package of the present disclosure may be applied to various types of electronic devices. To make the features and advantages of the present disclosure more comprehensible, various embodiments are cited as follow accompanying figures and described in detail.

### BRIEF DESCRIPTION OF THE FIGURES

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is an exploded view of a light-emitting element package according to some embodiments of the present disclosure.

FIG. 2A is an isometric view of the cup-shaped casing according to the embodiment of FIG. 1 of the present disclosure.

FIG. 2B is an isometric view of the connector according to the embodiment of FIG. 1 of the present disclosure.

FIG. 3A is an isometric view of a light-emitting element package according to some embodiments of the present disclosure.

FIG. 3B is a side view of a light-emitting element package according to some embodiments of the present disclosure.

FIG. 4A is a top view of a light-emitting element package according to some embodiments of the present disclosure.

FIG. 4B is a top view of a light-emitting element package according to some other embodiments of the present disclosure.

FIGS. 5A, 6A, 7A, 8A, 9A, and 10A are top views of a light-emitting element package at various manufacturing stages according to some embodiments of the present disclosure.

FIGS. 5B, 6B, 7B, 8B, 9B, and 10B are side views of a light-emitting element package at various manufacturing stages according to some embodiments of the present disclosure.

### DETAILED DESCRIPTION OF THE INVENTION

The following disclosure provides many different embodiments or examples for implementing the provided package structure. Specific examples of features and their configurations are described below to simplify the embodiments of the present disclosure, but certainly not to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In some embodiments of the present disclosure, terms about disposing and connecting, such as “disposing”, “connecting” and similar terms, unless otherwise specified, may refer to two features are in direct contact with each other, or may also refer to two features are not in direct contact with each other, wherein there is an additional connect feature between the two features. The terms about disposing and connecting may also include the case where both features are movable, or both features are mounted. In addition, ordinal numbers such as “first”, “second”, and the like used in the specification and claims are configured to modify different features or to distinguish different embodiments or ranges, rather than to limit the number, the upper or lower limits of features, and are not intended to limit the order of manufacture or arrangement of features.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

In some existing light-emitting element packages, the configuration of the electrical connector (e.g., the way it bends) often causes unexpected deformation (e.g., rotation or warping) of the electrical connection pad used to carry the light-emitting element. This makes it difficult for the light-emitting element subsequently disposed on the electrical connection pad to be well mounted on the electrical connection pad (e.g., displacement or detachment), which has an adverse effect on the manufacturing yield and device performance. In order to avoid such a situation, existing light-emitting element packages often impose many restrictions on the size and location of the light-emitting element. What is more, the configuration of the existing electrical connector is also prone to unexpected displacement (e.g., rotation or even detachment) of the light-emitting element package when it is mounted on other components due to the elasticity of the metal electrical connector itself.

In order to address at least the above-mentioned issues, the present disclosure provides a light-emitting element package. The extension portion of the electrical connector serving as the light-emitting element in the light-emitting element package is bent from the shorter-side surface of the cup-shaped casing to the longer-side surface. Such a configuration improves the flatness of the electrical connection pad used to support the light-emitting element, thereby increasing the position stability of the light-emitting element on the electrical connection pad. It is also worth noting that the configuration of the electrical connector provided by the present disclosure also prevents the displacement of the light-emitting element package caused by the elasticity of the metal electrical connector when it is mounted to other components. In addition, some embodiments of the present disclosure provide separate electrical connection pads that enable each light-emitting element to be independently controlled under the above-mentioned configuration.

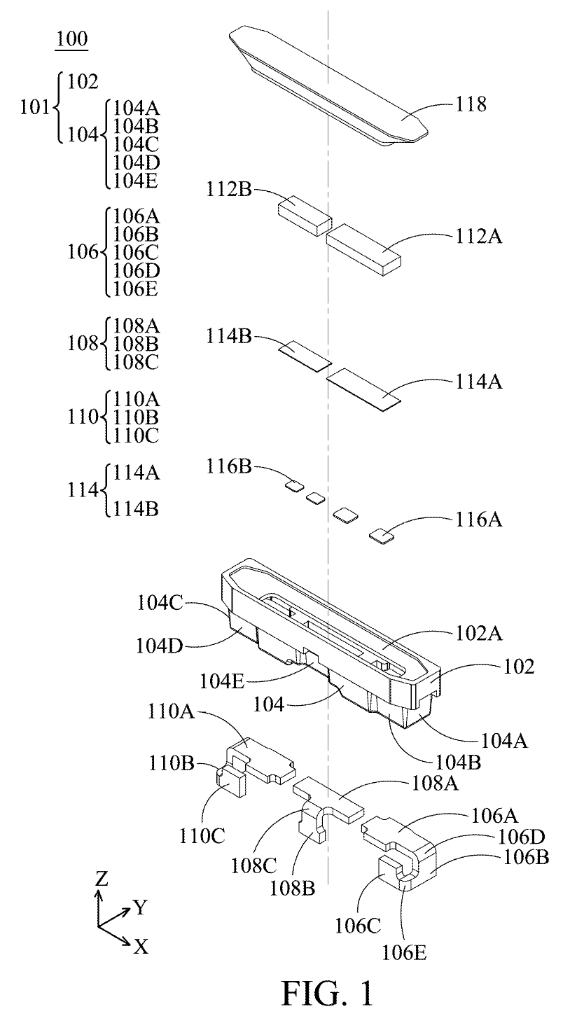

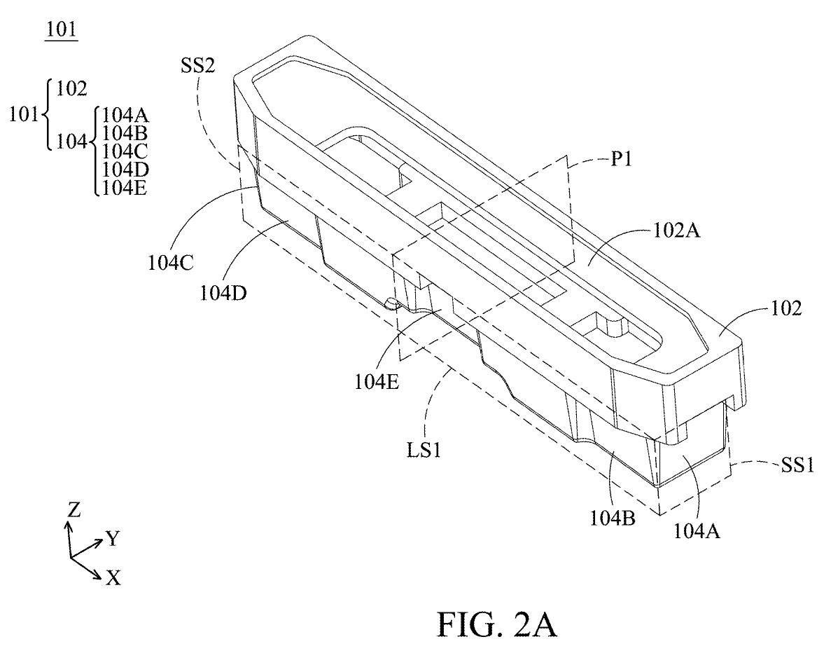

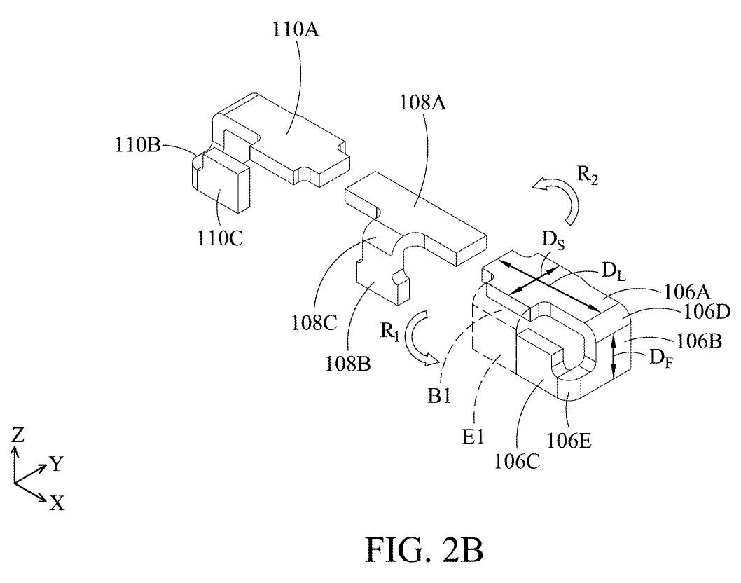

FIG. 1 is an exploded view of a light-emitting element package according to some embodiments of the present disclosure. FIG. 2A is an isometric view of a cup-shaped casing according to the embodiment of FIG. 1 of the present disclosure. FIG. 2B is an isometric view of a connector according to the embodiment of FIG. 1 of the present disclosure. It should be noted that for the purpose of simplicity and illustration, only a portion of the components of the semiconductor device are illustrated in the following figures. In fact, the light-emitting element package illustrated herein may include more or fewer components without departing from the spirit of the present disclosure.

Referring to FIG. 1, the light-emitting element package 100 includes a cup-shaped casing 101, a first connector 106, a second connector 110, a third connector 108, and a light-emitting portion 114 in some embodiments. In some embodiments, the cup-shaped casing 101 has an upper portion 102 and a lower portion 102. The first connector 106, the second connector 110, and the third connector 108 are separated from each other, and each includes a plurality of extensions and/or bends. The light-emitting portion 114 includes one or more light-emitting elements. The following provides a detailed description of each of the above components. The following description is provided in an order based on the functional relationships among the components, rather than being limited to their physical arrangement (e.g., from bottom to top or top to bottom), to more clearly illustrate the present disclosure.

Referring to FIG. 2A, the cup-shaped casing 101 has an upper portion 102 and a lower portion 104 (also referred to as the upper portion of the casing 102 and the lower portion of the casing 104) in some embodiments. As shown in FIG. 2A, in some embodiments, the upper portion of the casing 102 encloses a cup-like shaped receiving region 102A. In some embodiments, the receiving region 102A is used to accommodate each light-emitting element of the light-emitting portion 114 and the extension portions 106A, 110A, 108A of the first connector 106, the second connector 110, and the third connector 108, respectively.

As shown in FIG. 2 A , the lower portion of the casing 104 is below the upper portion of the casing 102 and is connected to the upper portion of the casing 102 . Referring to FIG. 2 A , the lower portion of the casing 104 has a first longer-side surface LS 1 extending along a first direction (e.g., the X direction in FIG. 2 A ) and a first shorter -side surface SS 1 extending along a second direction (e.g., the Y direction in FIG. 2 A ). In some embodiments, one side of the first longer-side surface LS 1 is connected to the first shorter-side surface SS 1 and is perpendicular to the first shorter-side surface SS 1 , but the present disclosure is not limited thereto. In some other embodiments, the first longer-side surface LS 1 and the first shorter-side surface SS 1 may be configured to a desired angle according to design requirements, such as 87°, 93°, or other angles.

Referring to FIGS. 1 and 2A, the lower portion 104 of the casing further has a first recessed portion 104A, a second recessed portion 104B, a third recessed portion 104C, a fourth recessed portion 104D, and a fifth recessed portion 104E, in some embodiments. In some embodiments, the recessed portions of the lower portion 104 are used to accommodate the bent portions and extended portions of the first connector 106, the second connector 110, and the third connector 108 extending outside the receiving region 102A (e.g., the bending portion 106D and the extension portions 106B, 106C, 106E in FIG. 1). Therefore, in some embodiments, the degree of recess (e.g., the depth and shape of the depression) of each recessed portion (e.g., the recessed portions 104A-104E shown in FIG. 2) of the lower portion 104 of the casing may be configured according to the size of the bending portion and extension portion of the connector extending outside the receiving region 102A.

Referring to FIG. 2A, the first recessed portion 104A is disposed on the first shorter-side surface SS1, and the third recessed portion 104C is disposed on the second shorter-side surface SS2 opposite to the first shorter-side surface SS1. The second recessed portion 104B, the fourth recessed portion 104D, and the fifth recessed portion 104E are disposed on the first longer-side surface LS1. In some embodiments, the fifth recessed portion 104E is on the first longer-side surface LS1 and is between the second recessed portion 104B and the fourth recessed portion 104D. The second recessed portion 104B and the fourth recessed portion 104D are mirror-symmetrical relative to the central plane P1 of the cup-shaped casing 101, as shown in FIG. 2A.

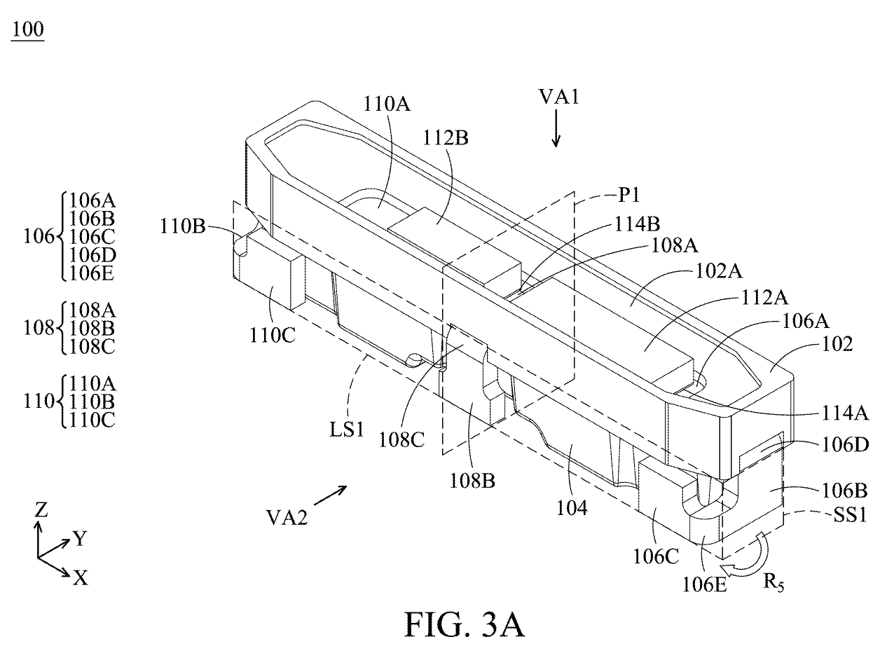

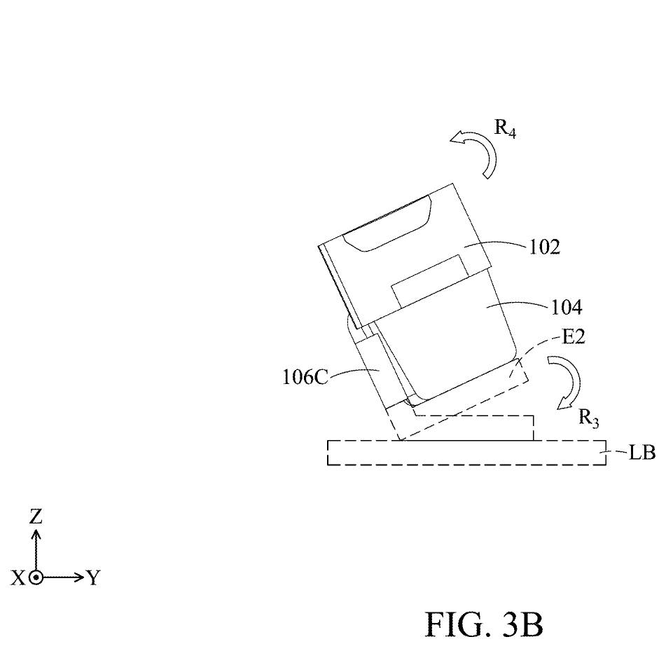

Reference is made to FIGS. 2B and 3A. FIG. 3A is an isometric view of a light-emitting element package according to some embodiments of the present disclosure. In some embodiments, the first connector 106 includes a first extension 106A, a second extension 106B, a third extension 106C, a first bend 106D, and a second bend 106E, as shown in FIG. 2B. In some embodiments, the first connector 106 serves as an electrical connector to electrically connect the light-emitting element thereon (e.g., the light-emitting element 114A in FIG. 3A) to an external circuit. In such an embodiment, the first connector 106 also serves as a support leg for fixing the light-emitting element package 100 to other components. For the sake of simplicity, the terms such as “first connector” and/or “first extension” in some of the following paragraphs omit their sequential numbers and are simply referred to as “connectors” and/or “extensions”. However, in these omitted paragraphs, the components referred to may still be clearly identified according to their respective numeral references.

As shown in FIGS. 2B and 3A, in some embodiments, the second connector 110 is disposed opposite to the first connector 106 based on the center plane P1 in the light-emitting element package 100 and is mirror-symmetrical with the first connector 106. It should be understood that in some embodiments of the present disclosure, the second connector 110 has the same components and performs the same functions as the first connector 106, except that it is arranged in an opposite orientation (e.g., the two are mirror-symmetrical to a central plane P1 of the cup-shaped housing 101, as shown in FIG. 3A). Accordingly, the description of the second connector 110 is omitted hereinafter as appropriate. In addition, unless otherwise specified, all components disposed on the first connector 106 in the embodiments of the present disclosure are also correspondingly disposed on the second connector 110.

As shown in FIG. 3A, in the above-mentioned embodiment, the first connector 106 is disposed on a first side of the lower portion of the casing 104 (e.g., disposed on one side of the central plane P1). Specifically, the first extension portion 106A of the first connector 106 is disposed on the upper surface of the lower portion of the casing 104, and has a flat shape in some embodiments (as shown in FIG. 2B). In some embodiments, the first extension portion 106A of the first connector 106 serves as a conductive pad for carrying a light-emitting element (e.g., a first light-emitting element 114A) of the light-emitting portion 114, as shown in FIG. 3A.

Referring to FIG. 3A, the second extension portion 106B of the first connector 106 is connected to the first extension portion 106A via the first bending portion 106D and extends on the first shorter-side surface SS1 of the lower portion of the casing 104. The third extension portion 106C of the first connector 106 is connected to the second extension portion 106B via the second bending portion 106E and extends on the first longer-side surface LS1 of the lower portion of the casing 104. In other words, in such an embodiment, the first connector 106 extends from the first extension portion 106A in the receiving region 102A, through a first bending portion 106D, out of the receiving region 102A, and is bent to a second extension portion 106B on the first shorter-side surface SS1. The second extension portion 106B is bent from the first shorter-side surface SS1 to the third extension portion 106C of the first longer-side surface LS1 via the second bending portion 106E.

Referring to FIGS. 2A and 3A together, in such an embodiment, the recess of the lower portion of the casing 104 corresponds to the extension of the connector and is used to accommodate the extension. For example, the first recessed portion 104A (as shown in FIG. 2A) of the lower portion of the casing 104 on the first shorter-side surface SS1 corresponds to the second extension portion 106B (as shown in FIG. 3A), and the second recessed portion 104B of the lower portion of the casing 104 on the first longer-side surface LS1 corresponds to the third extension portion 106C. In such an embodiment, the second connector 110 is symmetrically disposed with the first connector 106. Therefore, the fifth extension 110B of the second connector 110 also corresponds to the third recess 104B and is disposed therein. The sixth extension 110C of the second connector 110 corresponds to the fourth recess 104D and is disposed therein.

It is worth noting that in the above configuration of the present disclosure, the first extension portion 106A in the receiving region 102A is bent through the first bending portion 106D to the second extension portion 106B on the first shorter-side surface SS1, and then further bent through the second bending portion 106E to the third extension portion 106C on the first longer-side surface LS1. Such a configuration allows the first connector 106 to have a greater moment arm on the first extension portion 106A during bending, thereby reducing deformation or warping of the first extension portion 106A caused by the bending process.

Referring to FIG. 2B, in detail, when the first extension portion 106A is bent via the first bending portion 106D to the second extension portion 106B on the first shorter-side surface SS1, and further bent via the second bending portion 106E to the third extension portion 106C on the first longer-side surface LS1, such a bending manner utilizes a longer length D_{L} of the first extension portion 106A as a moment arm. In such an embodiment, the length D_{L} is also referred to as the moment arm D_{L}.

In contrast, when the first extension portion 106A is directly bent to an extension portion E1 on the first longer-side surface LS1 via a bending portion B1, such a bending manner utilizes a shorter length D_{S} of the first extension portion 106A as a moment arm. This causes the first extension portion 106A to rotate unexpectedly from the opposite direction (for example, the R₂ direction in FIG. 2B) due to the insufficient moment arm D_{S} during the bending process of the bending portion B1 to the extension portion E1 (for example, along the R₁direction in FIG. 2B). Such unexpected rotation causes unexpected warpage or tilt of the first extension portion 106A, thereby affecting the flatness and tightness of other components thereon. In some embodiments, the ratio D_{L}/D_{S} of the length D_{L} to the length D_{S} of the first extension portion 106A ranges from 1 to 3.

In some embodiments, the moment arm D_{L} on the first extension portion 106A is configured in relation to a force arm D_{F} of the second extension portion 106B on the first shorter-side surface SS1. Specifically, in some embodiments, the ratio D_{L}/D_{F} between the moment arm D_{L} on the first extension 106A and the force arm D_{F} of the second extension 106B on the first shorter-side surface SS1 of the lower portion of the casing 104 ranges from 1 to 3. It is noted that the above-mentioned ratio range is not arbitrarily selected or configured. For example, when D_{L}/D_{F} is too small (e.g., less than 1), the first extension 106A warps or tilts during the bending process due to insufficient moment arm D_{L}. When D_{L}/D_{F} is too large (e.g., greater than 3), the length of the first extension 106A (e.g., in the X direction ) is too long, which meaninglessly increases the size of the component or device.

Still referring to FIGS. 2B and 3A, in some embodiments, the third connector 108 is disposed on the first longer-side surface LS1 and disposed between the first connector 106 and the second connector 110. As shown in FIG. 2B, in such an embodiment, the third connector 108 has a seventh extension portion 108A, an eighth extension portion 108B and a third bending portion 108C. The seventh extension portion 108A is connected to the eighth extension portion 108B via the third bending portion 108C.

The third connector 108 has a function similar to the first connector 106. Therefore, in such an embodiment, the first connector 106, the second connector 110, and the third connector 108 are configured as electrical connectors that are electrically independent of each other in the light-emitting element package 100. In some embodiments, the first connector 106, the second connector 110, and the third connector 108 are collectively configured as a lead frame.

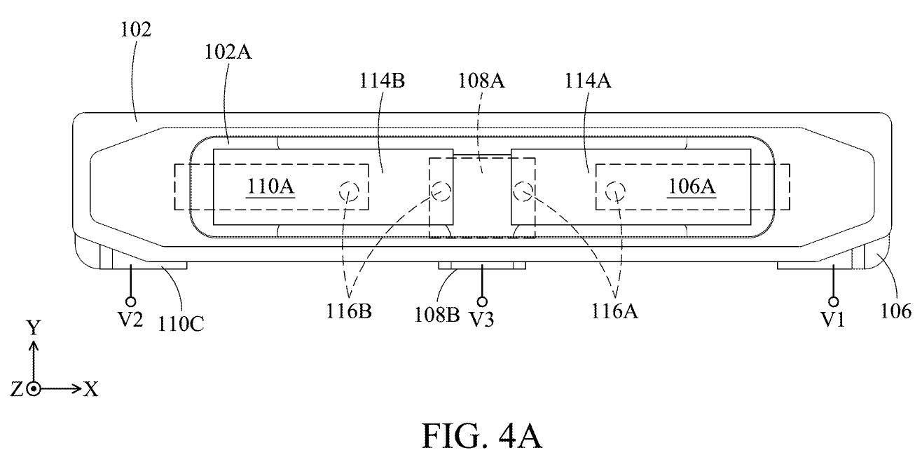

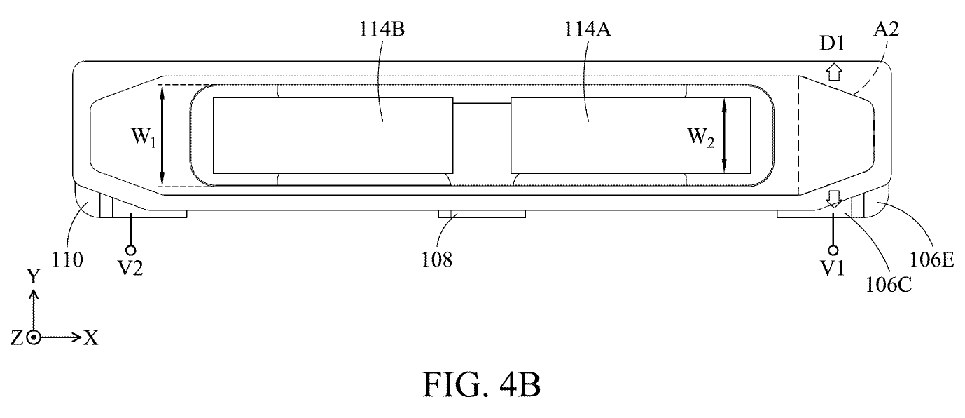

It is worth noting that such an electrically independent connector configuration enables each light-emitting element in the light-emitting element package 100 to be independently controlled. Specifically, in such an embodiment, the first flat extension portion 106A, the fourth extension portion 110A, and the seventh extension portion 108A of the first connector 106, the second connector 110, and the third connector 108 are configured as electrically independent electrical connection pads. These electrical connection pads provide different electrical connection configurations for the light-emitting elements (which will be illustrated with reference to FIGS. 4A and 4B).

Referring to FIG. 3A, in some embodiments, the seventh extension portion 108A of the third connector 108 is bent to the eighth extension portion 108B on the first longer-side surface LS1 via the third bending portion 108C. It should be particularly mentioned that the seventh extension portion 108A is directly bent to the eighth extension portion 108B on the first longer-side surface LS1 in this embodiment. However, in the embodiment with the third connector 108, the components above the seventh extension portion 108A in the third connector 108 are usually symmetrically disposed at both ends of the seventh extension portion 108A with respect to the center plane P1, thereby applying pressure to both ends of the seventh extension portion 108A in a symmetrical manner. Therefore, in these embodiments, the bending direction of the third connector 108 does not have too much impact on the components disposed thereon.

Reference is now made to FIGS. 3A and 3B. FIG. 3B is a side view of a light-emitting element package according to some embodiments of the present disclosure. It should be noted that some components in FIG. 3B are merely illustrative of possible movement positions thereof. This does not mean that these components must move toward these positions. In some other embodiments, these components may also move toward other positions.

It is also worth noting that in the embodiment of the present disclosure, the first connector 106, the second connector 110 and the third connector 108 only extend to the side surface of the cup-shaped casing 101 (for example, the first longer-side surface LS1 and/or the first shorter-side surface SS1) and do not further extend to the bottom surface of the casing below the side surface of the casing. In other words, the first connector 106, the second connector 110 and the third connector 108 do not have a portion at the bottom surface of the cup-shaped casing 101. Such a configuration helps prevent the unexpected displacement (for example, rotation) of the light-emitting element package 100 when the light-emitting element package 100 is mounted to other components (for example, a light board), which may otherwise occur due to the connectors being typically made of flexible metal materials. For example, as shown in FIG. 3A, the second extension portion 106B of the first connector 106 is bent along the corner of the lower portion 104 of the cup-shaped casing 101 to the third extension portion 106C on the first longer-side surface LS1 instead of continuing to bend downward on the first shorter-side surface SS1 to the bottom surface of the cup-shaped casing 101 (for example, in the direction of R₅ in FIG. 3A).

Referring to FIG. 3B, conversely, when the connector has a portion bent to the bottom surface 101BS of the cup-shaped casing 101 (for example, E2 bent from the extension portion 106C to the bottom surface 101BS of the cup-shaped casing 101), since the connector material is typically made of elastic metal, the extension portion E2 bent to the bottom surface 101BS may be detached from the bottom surface 101BS in a direction away from the bottom surface 101BS (for example, the clockwise direction R₃ shown in FIG. 3B). This causes the light-emitting element package 100 to generate an unexpected rotation (for example, the counterclockwise direction R₄ shown in FIG. 3B) or even detach from the light board LB when it is mounted to other components (for example, the light board LB).

Referring to FIGS. 1 and 3A, as shown in FIG. 1, in some embodiments, the light emitting portion 114 includes a first light emitting element 114A and a second light emitting element 114B. In such an embodiment, the first light-emitting element 114A and the second light-emitting element 114B each have a pair of first electrode structures 116A and a pair of second electrode structures 116B. In some embodiments, one of the pair of first electrode structures 116A and one of the pair of second electrode structures 116B are disposed on the third connector 108 (e.g., on the seventh extension portion 108A) and electrically connected thereto, while the other one of the pair of first electrode structures 116A and the other one of the pair of second electrode structures 116B are respectively disposed beneath the first light-emitting element 114A and the second light-emitting element 114B and are electrically connected thereto. Specifically, in some embodiments, the first light-emitting element 114A is disposed across the pair of first electrode structures 116A and is electrically connected to both of them. The second light-emitting element 114B is disposed across a pair of second electrode structures 116B and is electrically connected to both of them.

Referring to FIGS. 1 and 3A, in some embodiments, the first transparent substrate 112A and the second transparent substrate 112B are respectively disposed above the first light-emitting element 114A and the second light-emitting element 114B. In some embodiments, the first transparent substrate 112A and the second transparent substrate 112B are respectively used to protect the first light-emitting element 114A and the second light-emitting element 114B. In some embodiments, the first transparent substrate 112A and the second transparent substrate 112B may also be used to adjust the light emission path of the first light-emitting element 114A and the second light-emitting element 114B. Referring to FIG. 1, in some embodiments, the encapsulating material 118 is disposed in the receiving region 102A and covers the components within the receiving region 102A.

In summary, the light-emitting element package 100 provided by the present disclosure includes a cup-shaped casing 101 and a plurality of connectors (e.g., connectors 106, 108, 110). The connectors are used to electrically connect the light-emitting elements (e.g., light-emitting elements 114A, 114B) to the outside and serve as support legs for the light-emitting element package. In such an embodiment, some of the connectors (e.g., connectors 106, 110 disposed at the ends of the light-emitting element package) extend from the extension portion (106A, 110A) within the receiving region 102A, through the shorter-side surface SS1 of the cup-shaped casing 101, out of the receiving region 102A, and are bent from the shorter-side surface SS1 to the longer-side surface LS1 of the cup-shaped casing 101. Such a configuration effectively eliminates (or at least alleviates) the rotation and/or warping of the flat extension (e.g., extension 106A, 110A) caused by insufficient moment arm (e.g., moment arm on the flat extension) when the connector (e.g., connector 106, 110) is bent. As a result, the position of the components (e.g., light-emitting elements 114A, 114B) above the extension (e.g., extension 106A, 110A) in the receiving region 102A is effectively stabilized, thereby improving manufacturing yield and device performance. By way of counterexample, when the extension in the receiving region undergoes rotation and/or warping due to the bending of the rest of the connector, the electrode structure and light-emitting element above the extension may fail to be properly positioned on the intended flat surface, thereby resulting in issues such as insufficient structural strength and/or poor electrical contact.

In addition, the light-emitting element package provided by the present disclosure includes connectors that extend only to the side surfaces of the cup-shaped housing, but do not extend to the bottom surface thereof. Such a configuration effectively eliminates (or at least alleviates) the rotation or detachment of the light-emitting element package due to the elasticity of the connector material when the light-emitting element package is mounted to other components (as described above with reference to FIG. 3B).

Moreover, the configuration disclosed above (the connector is bent from the shorter-side surface of the cup-shaped casing to the longer-side surface) provides greater flexibility in the configuration of the receiving region of the cup-shaped casing. Specifically, the configuration disclosed above allows the cup-shaped casing to have a larger receiving region. It is also worth mentioning that some embodiments of the present disclosure may be further equipped with an independent electrical connector under the above configuration, thereby providing a more diverse electrical connection configuration of the light-emitting element (to be described with reference to FIGS. 4A and 4B).

FIG. 4A is a top view of a light-emitting element package according to some embodiments of the present disclosure. FIG. 4B is a top view of a light-emitting element package according to other embodiments of the present disclosure. The following will describe some operation modes and additional structural features of the light-emitting element package (e.g., light-emitting element package 100) according to some embodiments of the present disclosure with reference to FIGS. 4A and 4B.

Referring to FIG. 4A, in some embodiments, the extensions 106A, 110A, and 108A of the first connector 106, the second connector 110, and the third connector 108 are configured as independent electrical connection pads. As shown in FIG. 4A, in such an embodiment, the first light-emitting element 114A has a pair of first electrode structures 116A on the seventh extension 108A and the first extension 106A, respectively. The second light-emitting element 114B has a pair of second electrode structures 116B on the seventh extension 108A and the fourth extension 110A, respectively. In other words, the two first electrode structures 116A of the first light-emitting element 114A are electrically connected to the first extension 106A (thus electrically connected to the extension 106C) and the seventh extension 108A (thus electrically connected to the extension 108B), respectively. The two second electrode structures 116B of the second light-emitting element 114B are electrically connected to the fourth extension portion 110A (and thus electrically connected to the extension portion 110C) and the seventh extension portion 108A (and thus electrically connected to the extension portion 108B), respectively.

Still referring to FIG. 4A, in such an embodiment, the extension 106C, the extension 110C, and the extension 108B may be electrically connected to different potentials V1, V2, and V3, respectively. In such a configuration, the operation of the first light-emitting element 114A may be controlled by adjusting the potential difference between the potential V1 and the potential V3. The operation of the second light-emitting element 114B may be controlled by adjusting the potential between the potentials V2 and V3, without being affected by the first light-emitting element 114A. This is because, in such a configuration, one end of the electrode structures of the first light-emitting element 114A and the second light-emitting element 114B is electrically connected to the extension portion 108B and has the same potential V3. However, the operation of the first light-emitting element 114A and the second light-emitting element 114B may still be independently adjusted by the potentials V1 and V2 at the other ends of each.

On the other hand, in a configuration in which the connector 108 is not provided within the device or package, the middle of the first light-emitting element 114A and the second light-emitting element 114B (e.g., the location of the extension 108A) can only be directly electrically connected (e.g., the first electrode structure 116A on the extension 108A is directly connected to the second electrode structure 116B). In such a configuration, the first light-emitting element 114A and the second light-emitting element 114B can only form a series configuration in which they are electrically associated with each other, and cannot form a configuration that allows independent control as in the above-described embodiments.

Referring to FIG. 4B, the difference from FIG. 4A is that in this embodiment, only one end of the extension portion 106C and the extension portion 110C are electrically connected to the potentials V1 and V2, respectively, and the extension portion 108B is not electrically connected to the potential V3. In this configuration, the first light-emitting element 114A and the second light-emitting element 114B are connected in series.

Still referring to FIG. 4B, it is worth mentioning that this embodiment also has a configuration similar to the previous embodiment (the connector is bent from the shorter-side surface of the cup-shaped casing to the longer-side surface, as described in the previous embodiment). That is, the first connector 106 of this embodiment is also bent from the first shorter-side surface SS1 of the cup-shaped casing 101, through the extension portion 106E and then via the bending portion 106E, toward the first longer-side surface LS1. Such a configuration not only makes the extension portion 106A less likely to rotate or warp during the bending process (as described in the previous embodiment), but also provides more flexibility in the configuration of the cup-shaped casing 101.

Specifically, in these embodiments, the rotation or warping of the extension portion 106A is eliminated (or alleviated) due to the bending direction of the first connector 106. Accordingly, the cup-shaped casing 101 may have less material adjacent to the receiving region 102A (e.g., in region A2 of FIG. 4A). This allows the light-emitting element package to be configured with a larger receiving region 102A, thereby providing a larger arrangement space (for example, a larger die-bonding area) for the light-emitting element in the receiving region 102A. This is because when the bending direction of the first connector 106 has ensured that the extension 106A is not easily rotated or warped (or such rotation or warping is sufficiently reduced), it is no longer necessary (or not essential) to use such a large amount of material of the cup-shaped casing 101 adjacent to the receiving region 102A (e.g., area A2 in FIG. 4A) to press downward (e.g., along the Z-direction into the page in FIG. 4A) against the extension portion 106A to prevent such rotation or warping. This increases the adjustment space of the cup-shaped casing 101 material beside the receiving region 102A (for example, the casing material may expand in the width direction, such as D1). As a result, a larger receiving region 102A is provided, and a larger arrangement space for the light emitting elements therein is provided.

Specifically, in the embodiment shown in FIG. 4B, the receiving region 102A has a first width W₁ in the width direction (e.g., the Y direction). In some embodiments, the first width W₁ of the receiving region 102A in the width direction may be greater than 30% of the width W₂ of the first light-emitting element 114A and/or the second light-emitting element 114B. In some other embodiments, the first width W₁ may be greater than 50% of the width W₂.

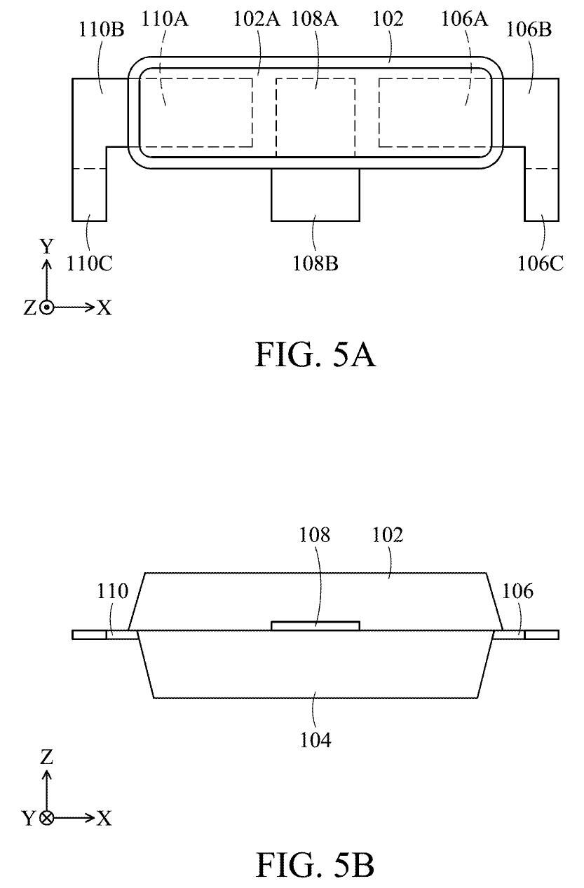

FIGS. 5A, 6A, 7A, 8A, 9A, and 10A are top views of the light-emitting element package according to some embodiments of the present disclosure at various manufacturing stages. FIGS. 5B-10B are side views of the light-emitting element package according to some embodiments of the present disclosure at various manufacturing stages. In more detail, FIGS. 5A-10A are top views observed from the VA1 perspective in FIG. 3A. FIGS. 5B, 6B, 7B, 8B, 9B, and 10B are side views observed from the VA2 perspective in FIG. 3A. The following will describe the manufacturing stages of the light-emitting element package (e.g., light-emitting element package 100 ) of some embodiments of the present disclosure with reference to FIGS. 5A-10A and 5B-10B.

Referring to FIGS. 5A and 5B, in some embodiments, a cup-shaped casing 101, a first connector 106, a second connector 110, and a third connector 108 are provided. As shown in FIG. 5B, in one embodiment, the boundaries between the first connector 106, the second connector 110, and the third connector 108, and the upper portion 102 and the lower portion 104 of the cup-shaped casing 101 are substantially at the same level.

As shown in FIG. 5A, in one embodiment, the first connector 106 and the second connector 110 are respectively disposed on two opposite shorter-side surfaces of the cup-shaped casing 101. The first extension portion 106A and the fourth extension portion 110A of the first connector 106 and the second connector 110 are in the receiving region 102A of the upper portion 102 of the cup-shaped casing 101. The remaining extension portions (106B, 106C, 110A, and 110C) of the first connector 106 and the second connector 110 are outside of the receiving region 102A. The seventh extension portion 108A of the third connector 108 is in the receiving region 102A, and the eighth extension portion 108B is outside of the receiving region 102A.

In some embodiments, the material of the cup-shaped casing 101 may be a suitable material for a light-emitting lamp casing in the art. For example, the above-mentioned material may be, for instance, an epoxy molding compound (EMC), poly(1,4-cyclohexylene dimethylene terephthalate) (PCT), or a silicone molding compound (SMC), or the like. In some embodiments, the cup-shaped casing 101 may be formed as a transparent casing. In other embodiments, a reflective material or a scattering material such as titanium dioxide (TiO₂) or silicon oxide (SiOₓ) may be added to the cup-shaped casing 101 as needed to adjust the light transmittance of the cup-shaped casing 101 or directly form the cup-shaped casing 101 into an opaque casing.

In some embodiments, the cup-shaped casing 101 may be formed by a molding method such as injection molding or transfer molding, and the recessed portions 104A-104E on the cup-shaped casing 101 (as described above with reference to FIG. 2A) may be integrally formed during the molding process. Specifically, in some embodiments, a mold of a corresponding shape may be formed according to the desired shape of the cup-shaped casing 101, and then the material of the cup-shaped casing 101 is injected into the mold and solidified by cooling. However, the present disclosure is not limited to forming the cup-shaped casing 101 in the above manner. In some other embodiments, the cup-shaped casing 101 may also be formed by other suitable methods in the art.

In some embodiments, the materials of the first connector 106, the second connector 110, and the third connector 108 may be a conductive metal material such as copper (Cu), and may be formed by, for example, a punching process. In one embodiment, the first connector 106, the second connector 110, and the third connector 108 are collectively configured as a lead frame punched from a metal strip. In some embodiments, the punching process of the first connector 106, the second connector 110, and the third connector 108 may also be combined with the molding process of the cup-shaped casing 101 to form a structure as illustrated in FIGS. 5A and 5B.

Specifically, in some embodiments, a metal strip is formed and cut into the shapes of the first connector 106, the second connector 110, and the third connector 108 by punching. Subsequently, the first connector 106, the second connector 110, and the third connector 108 are arranged at a desired position. Next, a casing molding process is performed according to the positions of the connectors to form a cup-shaped casing 101. The formed cup-shaped casing 101 wraps a portion of each of the first connector 106, the second connector 110, and the third connector 108 (e.g., 106A, 110A, and 108A), as shown in FIG. 5A.

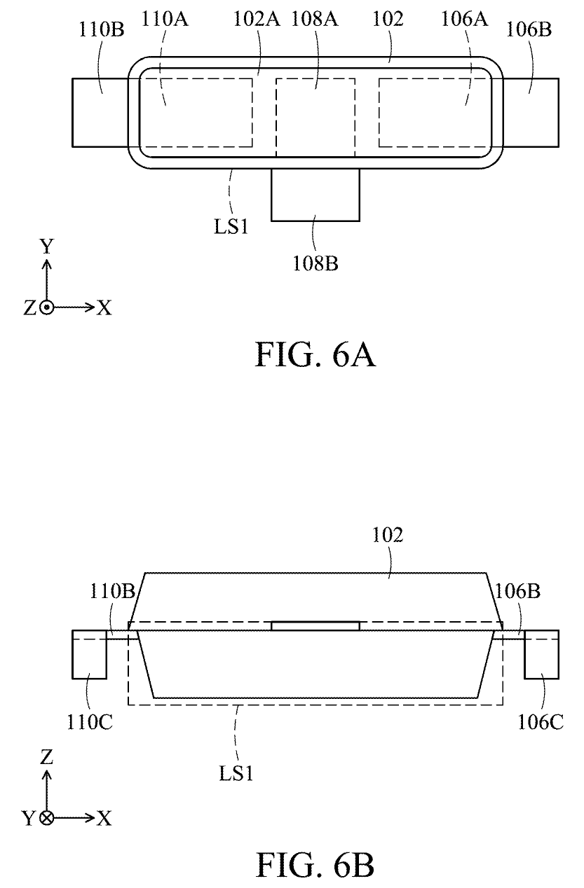

Reference is made to FIGS. 6A and 6B. Continue with the steps in FIGS. 5A and 5B. As shown in FIG. 6B, the third extension portion 106C and the sixth extension portion 110C of the first connector 106 and the second connector 110 are bent downward toward the direction of the first longer-side surface LS1 of the cup-shaped casing 101. As shown in FIG. 6A, the third extension portion 106C and the sixth extension portion 110C of the first connector 106 and the second connector 110 are bent downward and are not able to be observed in the top view.

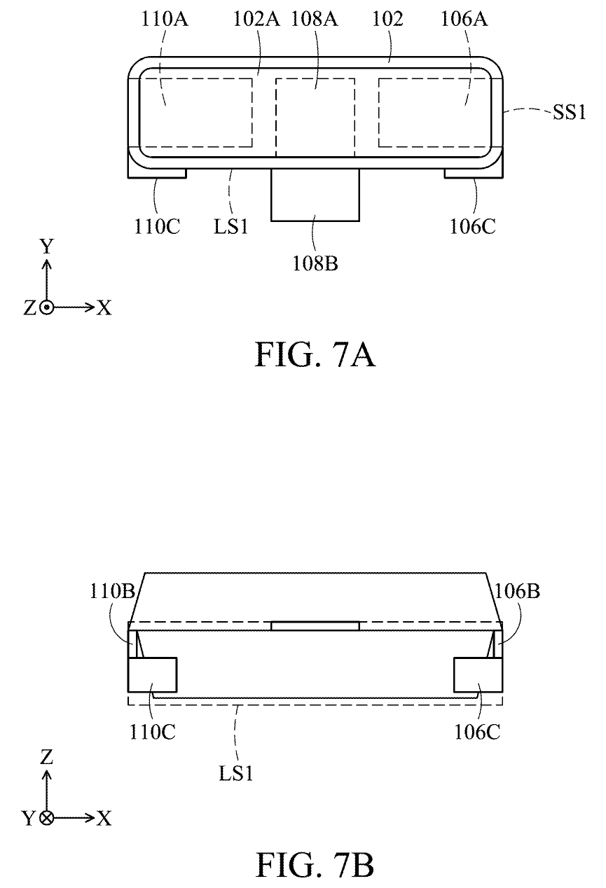

Reference is made to FIGS. 7A and 7B. Continue with the steps in FIGS. 6A and 6B. As shown in FIG. 7B, the second extension portion 106B and the fifth extension portion 110B of the first connector 106 and the second connector 110 are bent downward toward the direction of the shorter-side surface SS1 of the cup-shaped casing 101. As shown in FIG. 7A, such bending makes the third extension portion 106C and the sixth extension portion 110C of the first connector 106 and the second connector 110, respectively, to be positioned on the first longer-side surface LS1 of the cup-shaped casing 101 and received in the corresponding recessed portion of the lower portion of the casing 104 (not shown).

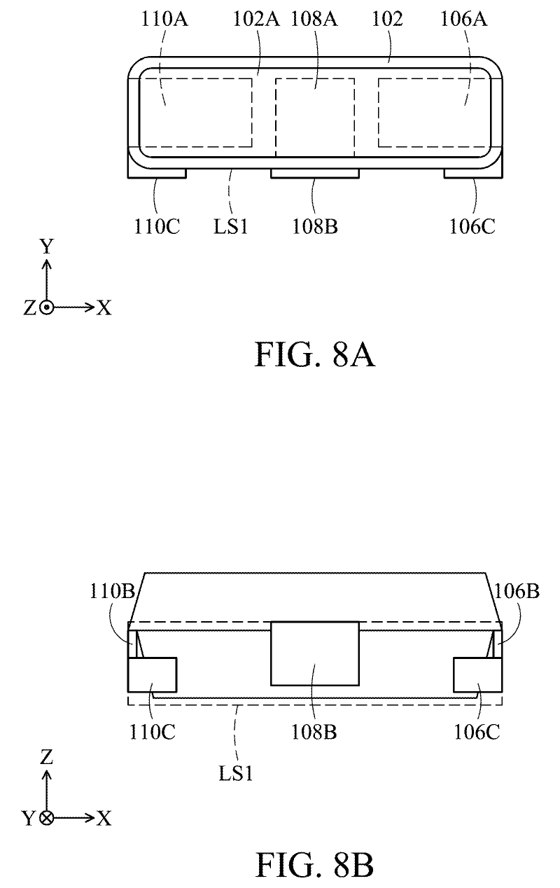

Reference is made to FIGS. 8A and 8B. Continue with the steps in FIGS. 7A and 7B. As shown in FIG. 8B, the eighth extension portion 108B of the third connector 108 is bent downward toward the first longer-side surface LS1 of the cup-shaped casing 101. As shown in FIG. 8A, such bending makes the eighth extension portion 108B of the third connector 108 located on the first longer-side surface LS1 of the cup-shaped casing 101 and received in the corresponding recessed portion of the lower portion of the casing 104 (not shown).

It is noted that the above-described bending steps for the connectors 106 and 110 (e.g., with reference to FIGS. 5A–7A and 5B–7B) and the bending step for the connector 108 (e.g., with reference to FIGS. 8A and 8B) are not necessarily performed in a specific order. In other words, in some other embodiments, the steps of bending the connectors 106 and 110 and the step of bending the connector 108 may also be interchanged as needed (for example, first bend the connector 108 and then bend the connectors 106 and 110). As long as the bending manner of each connector remains unchanged (e.g., as illustrated in the above embodiments), the present disclosure is not limited to any particular sequence described above. This is because in the present disclosure, the connectors 106, 110, and 108 are physically independent of each other and are not affected by each other.

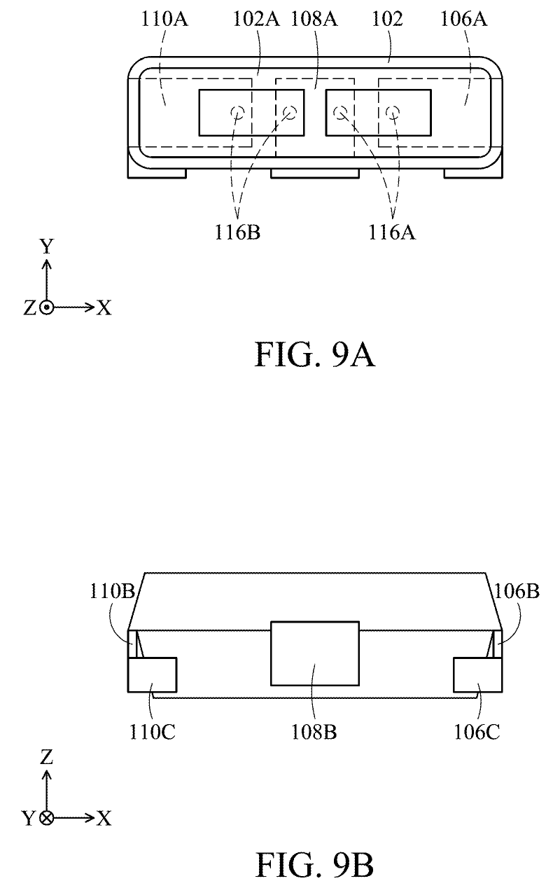

Reference is made to FIGS. 9A and 9B. It should be specifically noted that the steps illustrated in FIGS. 8A and 8B to 9A and 9B are described herein by way of example. However, with reference to FIG. 1, the steps between FIGS. 8A and 9A (or 8B and 9B) involve disposing a first electrode structure 116A on the first extension portion 106A, a second electrode structure 116B on the fourth extension portion 110A, and both a first electrode structure 116A and a second electrode structure 116B on the seventh extension portion 108A. In some embodiments, each electrode structure in the electrode structure pair (e.g., the pair of first electrode structures 116A or second electrode structures 116B described above) may also be individually referred to as a sub-electrode of the electrode structure.

Subsequently, the first light-emitting element 114A is formed on the pair of first electrode structures 116A formed in the above step, and the second light-emitting element 114B is formed on the pair of second electrode structures 116B. Next, a first transparent substrate 112A and a second transparent substrate 112B are formed on the first light-emitting element 114A and the second light-emitting element 114B, respectively.

In some embodiments, the material of the first electrode structure 116A and the second electrode structure 116B includes a conductive material of chromium (Cr), aluminum (Al), nickel (Ni), gold (Au), platinum (Pt), tin (Sn), copper (Cu), or a combination thereof. In some embodiments, the first electrode structure 116A and the second electrode structure 116B may be formed by a plating formation process, such as evaporation or electroplating, and may optionally be followed by a patterning process. In some embodiments, the first electrode structure 116A and the second electrode structure 116B may be disposed on the first extension portion 106A, the fourth extension portion 110A, and the seventh extension portion 108A by, for example, wire bonding.

In some embodiments, the first light-emitting element 114A and the second light-emitting element 114B include a light-emitting diode chip capable of emitting a specific wavelength. For example, the first light-emitting element 114A and the second light-emitting element 114B may include a light-emitting diode chip that emits blue light or a light-emitting diode chip that emits ultraviolet light, but the present disclosure is not limited thereto. In some embodiments, the material of the light-emitting diode chip may include an inorganic semiconductor material, such as a III-V compound, a II-VI compound, or other suitable materials. In some embodiments, the III-V compound may be a gallium nitride-based (GaN-based) material, a gallium arsenide-based (GaAs-based) material, or an arsenic phosphide-based (InP-based) material, and the II-VI compound may be a zinc sulfide-based (ZnS-based) material or a cadmium selenide-based (CdSe-based) material.

In some embodiments, the first light-emitting element 114A and the second light-emitting element 114B may be bonded to the first electrode structure 116A and the second electrode structure 116B by, for example, metal welding or conductive adhesive bonding.

In some embodiments, the materials of the first transparent substrate 112A and the second transparent substrate 112B may be the same or different soft light-transmitting materials. The soft light-transmitting material may be a transparent polymer material such as epoxy resin, silicone, or polymethylmethacrylate (PMMA). In some embodiments, the first transparent substrate 112A and the second transparent substrate 112B may be transparent polymer materials as described above and include reflective materials or scattering materials such as aluminum oxide (Al₂O₃) powder, aluminum nitride (AlN) powder, or silicon carbide (SiC) powder dispersed therein. In some embodiments, the first transparent substrate 112A and the second transparent substrate 112B may be formed by molding, laminating, coating process, or other suitable processes.

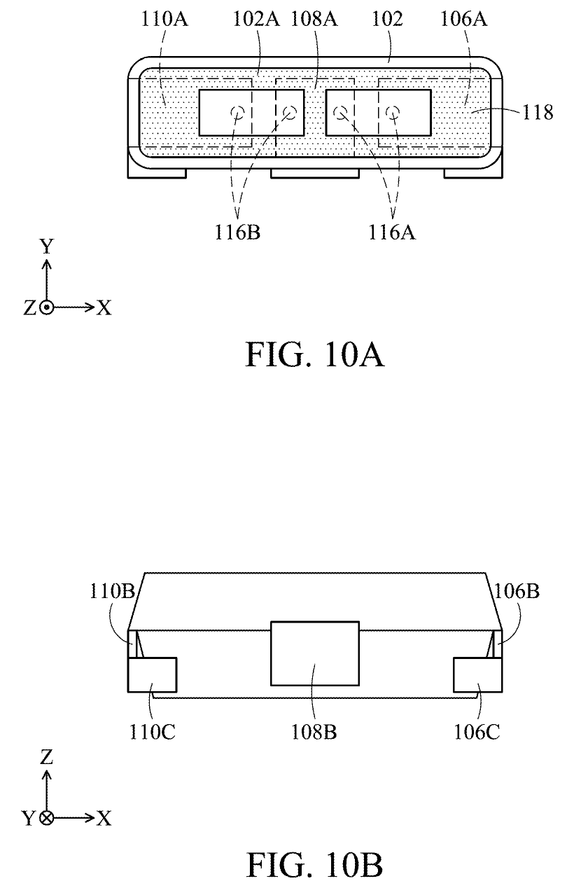

Reference is made to FIGS. 10A and 10B. Continue with the steps in FIGS. 9A and 9B. As shown in FIG. 10A, a packaging material 118 is formed in the receiving region 102A of the cup-shaped casing 101. In some embodiments, the packaging material 118 covers the transparent substrates 112A, 112B, the light-emitting elements 114A, 114B, and the electrode structures 116A, 116B formed in the receiving region 102A by the steps illustrated in the previous FIGS. 9A and 9B.

In some embodiments, the material of the packaging material 118 may be, for example, an epoxy molding compound (EMC), liquid molding compound (LMC), or silicone resin (polysiloxane silicone).

In some embodiments, the packaging material 118 may be formed by injection molding, but the present disclosure is not limited thereto. After the step of forming the packaging material 118, the manufacturing of the light-emitting element package (e.g., the light-emitting element package 100) according to some embodiments of the present disclosure is completed.

In summary, the present disclosure provides a light-emitting element package, wherein the connecting piece extends from the extension part in the receiving region of the cup-shaped casing on the shorter-side surface of the cup-shaped casing and bends from the shorter-side surface to the longer-side surface. Such a configuration alleviates the rotation or warping of the extension portion in the receiving region due to the bending of the portion connected to it. Not only that, such a configuration also provides greater flexibility in the spatial arrangement within the receiving region due to the improvement of the above issue, thereby providing a larger die-bonding area for the light-emitting element package.

Moreover, in the light-emitting element package provided in some embodiments of the present disclosure, the connector is only bent to the side surface of the cup-shaped casing, but not to the bottom surface of the cup-shaped casing. Such a configuration prevents unintended rotation or detachment of the light-emitting element package when mounted to other components, which may otherwise occur due to the elasticity of the material between the portions of the connector on the side surface of the cup-shaped casing and the portions on the bottom surface thereof (if present).

In addition, in some embodiments of the light-emitting element package provided by the present disclosure, the connectors are configured as electrically independent electrical connection pads. Such a configuration provides more options for electrical configurations of the light-emitting elements disposed thereon (e.g., configured for independent control or series connection).

Features in the disclosed embodiments can be mixed and matched arbitrarily as long as they do not violate the spirit of the disclosure or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting element package, comprising:
a cup-shaped casing, comprising:
an upper portion having a receiving region; and
a lower portion having a first longer-side surface and a first shorter-side surface, wherein the first longer-side surface extends in a first direction, and the first shorter-side surface extends in a second direction;
a first connector disposed on a first side of the lower portion, and comprising:
a first extension portion disposed on an upper surface of the lower portion of the casing;
a second extension portion connected to the first extension portion and extending on the first shorter-side surface; and
a third extension portion connected to the second extension portion and extending on the first longer-side surface; and
a first light-emitting element disposed in the receiving region, and electrically connected to the first connector.

2. The light-emitting element package as claimed in claim 1, wherein the first extension portion is connected to the second extension portion via a first bending portion, and the second extension portion is connected to the third extension portion via a second bending portion.

3. The light-emitting element package as claimed in claim 1, wherein the lower portion has a first recessed portion corresponding to the second extension portion on the first shorter-side surface and a second recessed portion corresponding to the third extension portion on the first longer-side surface.

4. The light-emitting element package as claimed in claim 1, wherein in a top view, the receiving region has a first width in the second direction at a position corresponding to the first light-emitting element and a second width in the second direction at a position corresponding to the first connector, and the second width is more than 30% of the first width.

5. The light-emitting element package as claimed in claim 1, further comprising:
a second connector disposed on a second side of the lower portion, and comprising:
a fourth extension portion disposed on an upper surface of the lower portion;
a fifth extension portion connected to the fourth extension portion and extending on a second shorter-side surface of the lower portion, wherein the second shorter-side surface is opposite to the first shorter-side surface in the first direction; and
a sixth extension portion connected to the fifth extension portion, and extending on the first longer-side surface; and
a second light-emitting element disposed in the receiving region and electrically connected to the second connector.

6. The light-emitting element package as claimed in claim 5, wherein the second connector and the first connector are mirror-symmetrical with respect to a central plane of the cup-shaped casing.

7. The light-emitting element package as claimed in claim 5, wherein the lower portion has a third recessed portion on the second shorter-side and a fourth recessed portion on the first longer-side, the fifth extension portion is disposed in the third recessed portion, and the sixth extension portion is disposed in the fourth recessed portion.

8. The light-emitting element package as claimed in claim 5, further comprising:
a third connector disposed between the first connector and the second connector, and comprising:
a seventh extension portion disposed on the upper surface of the lower portion; and
an eighth extension portion connected to the seventh extension portion and extending on the first longer-side surface, wherein
the third connector, the first connector, and the second connector are configured together as a lead frame.

9. The light-emitting element package as claimed in claim 8, wherein the seventh extension portion is connected to the eighth extension portion via a third bending portion.

10. The light-emitting element package as claimed in claim 5, further comprising:
a first electrode structure disposed below the first light-emitting element; and
a second electrode structure disposed below the second light-emitting element.

11. The light-emitting element package as claimed in claim 10, wherein the first electrode structure electrically connects the first light-emitting element to the first connector and the third connector, and the second electrode structure electrically connects the second light-emitting element to the second connector and the third connector.

12. The light-emitting element package as claimed in claim 5, further comprising:
a first transparent substrate disposed over the first light-emitting element in the receiving region;
a second transparent substrate disposed over the second light-emitting element in the receiving region; and
a packaging material disposed in the receiving region, and covering the first transparent substrate and the second transparent substrate.

13. A method for forming a light-emitting element package, comprising:
providing a cup-shaped casing comprising:
an upper portion having a receiving region; and
a lower portion having a first longer-side surface and a first shorter-side surface, wherein the first longer-side surface extends along a first direction and the first shorter-side surface extends along a second direction
disposing a first connector on a first side of the lower portion, the first connector comprises:
a first extension portion disposed on an upper surface of the lower portion;
a second extension portion connected to the first extension portion and extending on the first shorter-side surface of the lower portion; and
a third extension portion connected to the second extension portion and extending on the first longer-side surface of the lower portion;
bending the third extension portion toward the first longer-side surface of the lower portion and bending the second extension portion toward the first shorter-side surface of the lower portion;
making the second extension portion extends on the first shorter-side surface and the third extension portion extends on the first longer-side surface; and
providing a first light-emitting element disposed in the receiving region and electrically connected to the first connector.

14. The method for forming the light-emitting element package as claimed in claim 13, wherein the third extension portion is bent toward the first longer-side surface of the lower portion after bending the second extension portion toward the first shorter-side surface of the lower portion.

15. The method for forming the light-emitting element package as claimed in claim 13, wherein the second extension portion is bent toward the first shorter-side surface of the lower portion after bending the third extension portion toward the first longer-side surface of the lower portion of the casing.

16. The method for forming the light-emitting element package as claimed in claim 13, wherein bending the second extension portion toward the first shorter-side surface of the lower portion forms a first bending portion between the first extension portion and the second extension portion, and wherein the first bending portion is on the first shorter-side surface.

17. The method for forming the light-emitting element package as claimed in claim 13, wherein the lower portion further comprises:
a first recessed portion disposed on the first shorter-side surface;
a second recessed portion disposed on the first longer-side surface near the first shorter-side surface;
a third recessed portion disposed on a second shorter-side surface opposite to the first shorter-side surface;
a fourth recessed portion disposed on the first longer-side surface near the second shorter-side surface ; and
a fifth recessed portion disposed on the first longer-side surface and between the second recessed portion and the fourth recessed portion, wherein
after the second extension portion is bent toward the first shorter-side surface, the second extension portion of the first connector is accommodated in the first recessed portion, and the third extension portion is accommodated in the second recessed portion.

18. The method for forming a light-emitting element package as claimed in claim 17, further comprising:
providing a second connector comprising:
a fourth extension portion disposed in the receiving region;
a fifth extension portion connected to the fourth extension portion and extending out of the receiving region through a second shorter-side surface of the lower portion along the first direction, and the second shorter-side surface is opposite to the first shorter-side surface; and
a sixth extending portion connected to the fifth extending portion and extending along the second direction;
bending the sixth extension portion toward the first longer-side surface of the lower portion;
bending the fifth extension portion toward the second shorter-side surface so that the fifth extension portion is accommodated in the third recessed portion of the lower portion, and the sixth extension portion is accommodated in the fourth recessed portion of the lower portion; and
providing a second light-emitting element that is disposed on the second connector and electrically connected to the second connector.

19. The method for forming a light-emitting element package as claimed in claim 18, further comprising:
providing a third connector, comprising:
a seventh extension portion disposed in the receiving region of the upper portion between the first extension portion and the fourth extension portion; and
an eighth extension portion connected to the seventh extension portion and extending out of the receiving region through the first longer-side surface of the lower portion along the second direction; and
bending the eighth extension portion toward the first longer-side surface of the lower portion;
making the eighth extension portion is accommodated in the fifth recessed portion of the lower portion, wherein
the third connector is collectively configured as a lead frame with the first connector and the second connector.

20. The method for forming a light-emitting element package as claimed in claim 19, further comprising:
providing a first electrode structure electrically connected to the first light-emitting element to the first connector and the third connector; and
providing a second electrode structure electrically connected to the second light-emitting element to the second connector and the third connector, wherein
the first electrode structure comprises:
a first sub-electrode configured electrically connects the first light-emitting element to the first connector; and
a second sub-electrode configured electrically connects the first light-emitting element to the third connector; and
the second electrode structure comprises:
a third sub-electrode configured electrically connects the second light-emitting element to the second connector; and
a fourth sub-electrode configured electrically connects the second light-emitting element to the third connector.
